(19) United States
(12) Patent Application Publication
(10) Pub. No.: US 2025/0105764 A1
(43) Pub. Date: Mar. 27, 2025

(54) HOLDING DEVICE

(71) Applicant: Niterra Co., Ltd., Nagoya-shi, Aichi (JP)

(72) Inventors: Yuji KAWAMURA, Nagoya-shi (JP); Takashi YAMAGUCHI, Nagoya-shi (JP); Kaori SHIMAZU, Nagoya-shi (JP); Hideki UEMATSU, Nagoya-shi (JP)

(21) Appl. No.: 18/719,940

(22) PCT Filed: Dec. 23, 2022
(86) PCT No.: PCT/JP2022/047607

§ 371 Date: Jun. 14, 2024

(30) Foreign Application Priority Data
Jan. 14, 2022 (JP) 2022-004420

(51) Int. Cl. H02N 13/00; B23Q 3/15

(52) U.S. Cl. CPC H02N 13/00; B23Q 3/15

(57) ABSTRACT

This holding device comprises: the first plate member having the first surface and a second surface; a disk-shaped second plate-shaped member which has a diameter larger than that of the first surface and has a third surface, a fourth surface, and a heating resistor, a first joining layer which is disposed between the second surface and the third surface and is for joining the first plate member and the second plate member, a base member having a fifth surface and a sixth surface; and a second joining layer which is disposed between the fourth surface and the fifth surface and is for joining the second plate member and the base member. The outer circumference of at least one of the first junction layer and the second junction layer is located so as to be withdrawn more toward the inner side than the outer circumference of the second plate member.

### CROSS-REFERENCE TO RELATED APPLICATIONS

This is a national phase application filed under 35 U.S.C. 371 of PCT/JP2022/047607 filed on Dec. 23, 2022, which claims the benefit of priority from the prior Japanese Patent Application No. 2022-004420 filed on Jan. 14, 2022, the entire contents of which are incorporated herein by reference.

### TECHNICAL FIELD

The present disclosure relates to a holding device that holds an object.

### BACKGROUND ART

As a holding device that holds an object, for example, a holding device that is described in PTL 1 is known. In such a holding device, in order to precisely control the temperature of the object that is held, it is important that the temperature of a holding surface be made uniform. Therefore, in the holding device, a plate-shaped member that holds an object includes an upper portion (a first plate-shaped member), a lower portion (a second plate-shaped member), and an intermediate joining portion (a first joining layer), and, before the upper portion and the lower portion are joined to each other, a portion of a heater electrode provided at the lower portion is removed to adjust the electrical resistance of the heater electrode. Then, the lower portion and the upper portion are joined to each other by the intermediate joining portion to make uniform the temperature of the holding surface of the plate-shaped member.

### RELATED ART DOCUMENTS

### Patent Literature

PTL 1: International Publication No. 2020/213368

### SUMMARY OF INVENTION

### Technical Problem

However, in the holding device above, since a holding member includes two plate-shaped members (including joining layers), and thus the thickness per plate-shaped member becomes small, so that each plate-shaped member tends to be largely warped. Therefore, when the plate-shaped member (the lower portion) is joined to a base member, although the plate-shaped member is partly unwarped, the warp may remain on an outer side of the plate-shaped member to completion of a product. This is because, since a joining layer does not exist on an outer side with respect to an outermost periphery of the plate-shaped member (the lower portion), a force that causes the warping to follow the base member does not act from the surrounding, as a result of which unwarping is unlikely to be performed on the outer side of the plate-shaped member.

When the warp remains on the outer side of the plate-shaped member (the lower portion), variations in the thickness of the joining layers are increased at an outer portion thereof. For example, when the plate-shaped member (the lower portion) is warped in a convex form on a lower side (convex form on a side of the base member) of the plate-shaped member, at an outer side of the joining layer that joins the base member and the plate-shaped member (the lower portion) to each other, the thickness of the joining layer is increased toward an outer periphery, whereas, at an outer side of the joining layer that joins the plate-shaped member (the upper portion) and the plate-shaped member (the lower portion) to each other, the thickness of the joining layer is decreased toward the outer periphery.

In this way, when variations in the thicknesses of the joining layers are increased, variations in heat conduction at the joining layers are increased. Since a large difference occurs between the heat conduction at a portion where variations in the thickness of each of the joining layers are small and the heat conduction at a portion where variations in the thickness of each of the joining layers are large, temperature uniformity at the holding surface may be adversely affected.

Accordingly, the present disclosure has been made to overcome the problems above, and it is an object of the present disclosure to provide a holding device that is capable of improving temperature uniformity at a first surface (a holding surface) that holds an object.

### Solution to Problem

To this end, according to an aspect of the present disclosure, there is provided a holding device including:
a disk-shaped first plate-shaped member that has a first surface and a second surface provided on a side opposite to the first surface;
a disk-shaped second plate-shaped member that has a third surface and a fourth surface provided on a side opposite to the third surface, that includes a heating resistor, and that has a diameter larger than a diameter of the first surface;
a first joining layer that is disposed between the second surface and the third surface and that joins the first plate-shaped member and the second plate-shaped member to each other;
a base member that has a fifth surface and a sixth surface provided on a side opposite to the fifth surface; and
a second joining layer that is disposed between the fourth surface and the fifth surface and that joins the second plate-shaped member and the base member to each other,
in which, in the holding device that holds an object on the first surface of the first plate-shaped member,
when viewed from a stacking direction of the first plate-shaped member, the second plate-shaped member, and the base member, an outer periphery of at least one of the first joining layer and the second joining layer is positioned at a location that is retreated on an inner side with respect to an outer periphery of the second plate-shaped member.

In this way, when viewed from the stacking direction, by positioning the outer periphery of at least one of the first joining layer or the second joining layer at a location that is retreated on the inner side with respect to the outer periphery of the second plate-shaped member, the first joining layer or the second joining layer is eliminated at an outer portion where variations in the thickness of the first joining layer and variations in the thickness of the second joining layer are increased due to the warping of the second plate-shaped member. In other words, the first joining layer or the second joining layer is no longer formed at the outer portion where variations in the thickness of the first joining layer and variations in the thickness of the second joining layer are increased. Therefore, a space (which becomes a vacuum when the device is used) is formed between an outer portion of the second plate-shaped member and the first plate-shaped member or the base member. Almost no heat conduction occurs in this space portion.

Therefore, heat moves between the second plate-shaped member and the first plate-shaped member through the first joining layer where variations in the thickness are decreased, and heat moves between the second plate-shaped member and the base member through the second joining layer where variations in the thickness are decreased. Therefore, the movement of heat between the second plate-shaped member and the first plate-shaped member can be made uniform or the movement of heat between the second plate-shaped member and the base member can be made uniform, and thus temperature uniformity at the first surface that holds an object can be improved.

Note that, when both the first joining layer and the second joining layer are disposed so as to be retreated with respect to the outer periphery of the second plate-shaped member, the outer periphery of the first joining layer and the outer periphery of the second joining layer are disposed so as not to match each other, that is, the outer periphery of the first joining layer and the outer periphery of the second joining layer are disposed so as to be displaced from each other when viewed from the stacking direction.

In the holding device above, it is preferable that, when viewed from the stacking direction, the outer periphery of the first joining layer and the outer periphery of the second joining layer be positioned on an outer side with respect to an outer periphery of the first surface.

Here, when the outer periphery of the first joining layer or the outer periphery of the second joining layer is positioned on an inner side with respect to the outer periphery of the first surface when viewed from the stacking direction, almost no movement of heat occurs between the second plate-shaped member and the first plate-shaped member or between the second plate-shaped member and the base member at a location directly below the vicinity of the outer periphery of the first surface (in a projection plane of the first surface). This deteriorates temperature uniformity at the first surface.

Therefore, when viewed from the stacking direction, by positioning the outer periphery of the first joining layer and the outer periphery of the second joining layer on the outer side with respect to the outer periphery of the first surface, the outer periphery of the first joining layer and the outer periphery of the second joining layer are no longer positioned on the inner side with respect to the outer periphery of the first surface. Therefore, it is possible to reliably improve temperature uniformity at the first surface.

In the holding device above, it is preferable that, when a bending rigidity of the base member is higher than a bending rigidity of the second plate-shaped member, the outer periphery of the second joining layer be positioned on an outer side with respect to the outer periphery of the first joining layer, when viewed from the stacking direction.

In this way, when the bending rigidity of the base member is higher than the bending rigidity of the second plate-shaped member, when viewed from the stacking direction, by positioning the outer periphery of the second joining layer on the outer side with respect to the outer periphery of the first joining layer, the contact area where the second plate-shaped member and the second joining layer contact each other becomes larger than the contact area where the second plate-shaped member and the first joining layer contact each other. Therefore, it is possible to effectively unwarp the second plate-shaped member by causing the second plate-shaped member to follow the base member whose bending rigidity is higher than the bending rigidity of the second plate-shaped member.

When the second plate-shaped member is unwarped, variations in the thickness of the first joining layer and variations in the thickness of the second joining layer are decreased. Therefore, the movement of heat between the second plate-shaped member and the first plate-shaped member or the base member is made more uniform, and thus temperature uniformity at the first surface can be further improved.

In the holding device mentioned above, it is preferable that, when a bending rigidity of the first plate-shaped member is higher than a bending rigidity of the second plate-shaped member, the outer periphery of the first joining layer be positioned on an outer side with respect to the outer periphery of the second joining layer, when viewed from the stacking direction.

In this way, when the bending rigidity of the first plate-shaped member is higher than the bending rigidity of the second plate-shaped member, when viewed from the stacking direction, by positioning the outer periphery of the first joining layer on the outer side with respect to the outer periphery of the second joining layer, the contact area where the second plate-shaped member and the first joining layer contact each other becomes larger than the contact area where the second plate-shaped member and the second joining layer contact each other. Therefore, it is possible to effectively unwarp the second plate-shaped member by causing the second plate-shaped member to follow the first plate-shaped member whose bending rigidity is higher than the bending rigidity of the second plate-shaped member.

When the second plate-shaped member is unwarped and becomes small, variations in the thickness of the first joining layer and variations in the thickness of the second joining layer are decreased. Therefore, the movement of heat between the second plate-shaped member and the first plate-shaped member or the base member is made more uniform, and thus temperature uniformity at the first surface can be further improved.

In the holding device mentioned above, it is preferable that, when the second plate-shaped member and the base member are made of different types of materials and there is a difference between a thermal expansion coefficient of the second plate-shaped member and a thermal expansion coefficient of the base member, the second joining layer be made thicker than the first joining layer.

Here, when the second plate-shaped member and the base member are made of different types of materials, the second joining layer may be damaged due to a difference between the thermal expansion coefficients. When the second joining layer is damaged, variations occur in heat conduction between the second plate-shaped member and the base member through the second joining layer, and thus the movement of heat becomes ununiform, deteriorating temperature uniformity at the first surface.

Accordingly, when the second plate-shaped member and the base member are made of different types of materials and thus there is a difference between the thermal expansion coefficients, by causing the second joining layer to be thicker than the first joining layer, it is possible to reliably prevent damage to the second joining layer caused by the difference between the thermal expansion coefficient of the second plate-shaped member and the thermal expansion coefficient of the base member. Therefore, heat is properly conducted between the second plate-shaped member and the base member through the second joining layer, and thus temperature uniformity at the first surface can be reliably improved.

### Advantageous Effects of Invention

According to the present disclosure, it is possible to provide a holding device that is capable of improving temperature uniformity at a first surface (a holding surface) that holds an object.

### BRIEF DESCRIPTION OF DRAWINGS

FIG. 1 is a perspective view of an electrostatic chuck of a first embodiment.

FIG. 2 is an XZ cross-sectional view of the electrostatic chuck of the first embodiment.

FIG. 3 is an XY cross-sectional view of the electrostatic chuck of the first embodiment.

FIG. 4 is a diagram illustrating the factors that cause variations in the thicknesses of joining layers in a structure of a related art.

FIG. 5 is a cross-sectional view showing a schematic structure of the electrostatic chuck of the first embodiment.

FIG. 6 is a cross-sectional view of a schematic structure showing an electrostatic chuck of a second embodiment.

### DESCRIPTION OF EMBODIMENTS

A holding device of an embodiment according to the present disclosure is described in detail with reference to the drawings. In the present embodiment, as the holding device, for example, an electrostatic chuck that is used in a semiconductor manufacturing apparatus, such as a deposition apparatus (a CVD deposition apparatus, a sputtering deposition apparatus, or the like) or an etching apparatus (a plasma etching apparatus or the like) is exemplified and described.

### First Embodiment

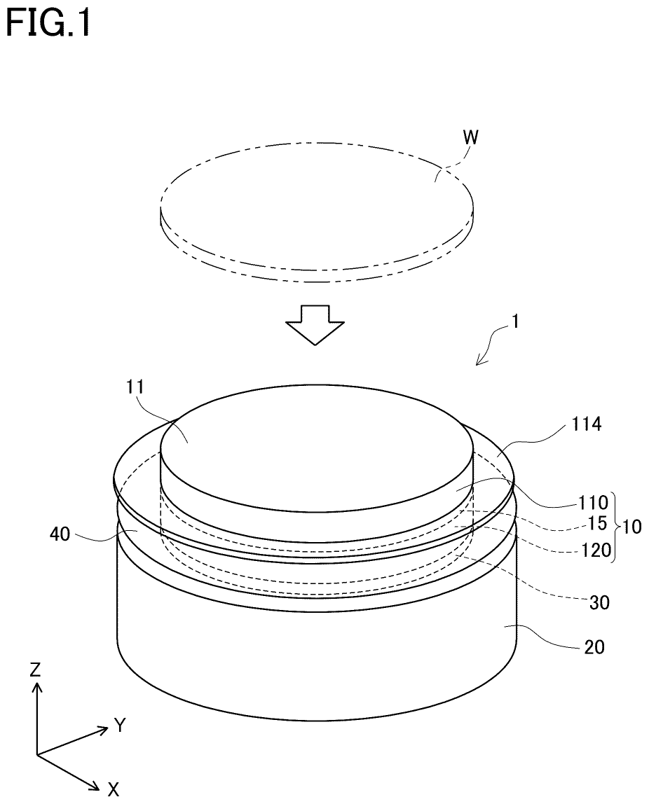

First, an electrostatic chuck 1 of a first embodiment is described with reference to FIGS. 1 to 3. The electrostatic chuck 1 of the present embodiment is a device that holds a semiconductor wafer W (an object) by attracting the semiconductor wafer W by electrostatic attraction, and is used, for example, for fixing the semiconductor wafer W inside a vacuum chamber of a semiconductor manufacturing apparatus. As shown in FIG. 1, the electrostatic chuck 1 includes a plate-shaped member 10, a base member 20, and a joining layer 30 that joins the plate-shaped member 10 and the base member 20 to each other.

In the description below, for explanatory convenience, as shown in FIG. 1, XYZ axes are defined. Here, the Z axis is an axis in an axial direction (an up-down direction in FIG. 1) of the electrostatic chuck 1, and the X axis and the Y axis are axes in radial directions of the electrostatic chuck 1.

As shown in FIG. 1, the plate-shaped member 10 is a disk-shaped member, and has a holding surface 11 that is an upper surface and that holds the semiconductor wafer W, and a lower surface 12 that is provided on a side opposite to the holding surface 11 in a thickness direction (a direction that corresponds to a Z axis direction) of the plate-shaped member 10. The plate-shaped member 10 includes a first plate-shaped member 110, a second plate-shaped member 120, and an intermediate joining layer 15 that joins the first plate-shaped member 110 and the second plate-shaped member 120 to each other. The diameter of the plate-shaped member 10 (a portion excluding a flange portion 114 described below) is, for example, about 50 mm to 500 mm (ordinarily, about 200 mm to 350 mm); and the thickness of the plate-shaped member 10 is, for example, about 1 mm to 10 mm.

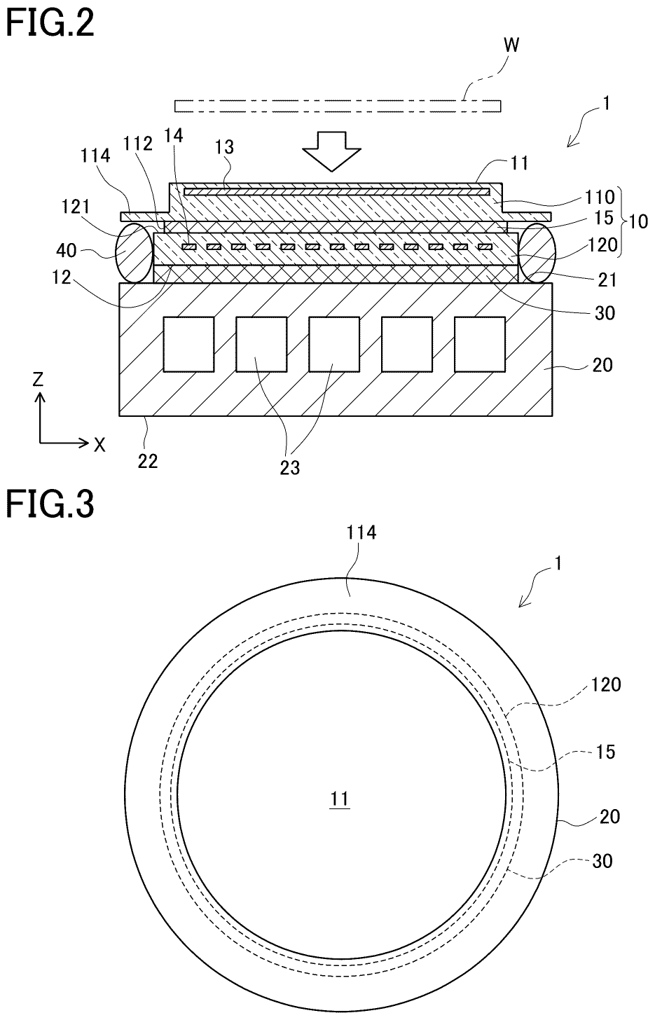

As shown in FIG. 2, the first plate-shaped member 110 has the holding surface 11 that is the upper surface of the plate-shaped member 10, and a lower surface 112 that is provided on a side opposite to the holding surface 11 in the thickness direction (the direction that corresponds to the Z axis direction). Note that the holding surface 11 is an example of a “first surface” of the present disclosure, and the lower surface 112 is an example of a “second surface” of the present disclosure. The first plate-shaped member 110 includes the flange portion 114 that protrudes in a planar direction along an entire outer periphery of the first plate-shaped member 110.

A chuck electrode 13 is disposed inside the first plate-shaped member 110. The chuck electrode 13 has, for example, a substantially circular shape when viewed in the Z axis direction, and is made of a conductive material (such as tungsten or molybdenum). By supplying electrical power to the chuck electrode 13 from a not-shown power source, an electrostatic attraction (an attraction force) is generated, and the semiconductor wafer W is attracted and fixed to the holding surface 11 of the plate-shaped member 10 by the electrostatic attraction. Note that, although the chuck electrode 13 is substantially circular as a whole, the chuck electrode 13 may be divided into semicircular shapes or fan shapes.

The first plate-shaped member 110 is made of ceramic. As the ceramic, various types of ceramic are used. However, from the viewpoints of strength, wear resistance, plasma resistance, and others, it is preferable to use, for example, ceramic whose main component is aluminum oxide (alumina, Al₂O₃) or aluminum nitride (AlN). It is preferable that a porosity of the first plate-shaped member 110 be lower than a porosity of the second plate-shaped member 120. Note that the so-called main component here refers to a component having the largest content percentage (for example, a component having a volume percentage of 90 vol % or more).

As shown in FIG. 2, the second plate-shaped member 120 has the lower surface 12 of the plate-shaped member 10, and an upper surface 121 that is provided on a side opposite to the lower surface 12 in the thickness direction (the direction that corresponds to the Z axis direction). The outside diameter of the second plate-shaped member 120 (an outer peripheral diameter of the upper surface 121 or the lower surface 12) is larger than the outside diameter of the portion of the first plate-shaped member 110 excluding the flange portion 114 (an outer peripheral diameter of the holding surface 11). Note that the upper surface 121 is an example of a “third surface” of the present disclosure, and the lower surface 12 is an example of a “fourth surface” of the present disclosure.

A heater electrode 14 is disposed inside the second plate-shaped member 120. The heater electrode 14 constitutes, for example, a pattern that extends in a substantially spiral form when viewed in the Z axis direction, and is made of a conductive material (such as tungsten, molybdenum, or platinum). By supplying electrical power to the heater electrode 14 from a not-shown power source and heating the heater electrode 14, the holding surface 11 and thus the semiconductor wafer W are heated. Note that the heater electrode 14 is an example of a “heating resistor” of the present disclosure.

Similarly to the first plate-shaped member 110, the second plate-shaped member 120 is also made of ceramic. As the ceramic, various types of ceramic are used. However, from the viewpoints of strength, wear resistance, plasma resistance, and others, it is preferable to use, for example, ceramic whose main component is aluminum oxide (alumina, Al₂O₃) or aluminum nitride (AlN).

As shown in FIGS. 1 and 2, the intermediate joining layer 15 is disposed between the lower surface 112 of the first plate-shaped member 110 and the upper surface 121 of the second plate-shaped member 120, and joins the first plate-shaped member 110 and the second plate-shaped member 120 to each other. As shown in FIG. 3, when viewed in the Z-axis direction (when viewed from the stacking direction), an outer periphery of the intermediate joining layer 15 is positioned at a location that is retreated on an inner side with respect to an outer periphery of the second plate-shaped member 120. When viewed in the Z-axis direction, the outer periphery of the intermediate joining layer 15 is positioned on an outer side with respect to an outer periphery of the holding surface 11 of the first plate-shaped member 110. That is, when viewed in the Z-axis direction, the outer periphery of the intermediate joining layer 15 is positioned between the outer periphery of the holding surface 11 of the first plate-shaped member 110 and the outer periphery of the second plate-shaped member 120.

Note that the intermediate joining layer 15 is an example of a “first joining layer” of the present disclosure. The lower surface 112 of the first plate-shaped member 110 and the upper surface 121 of the second plate-shaped member 120 are thermally connected to each other by the intermediate joining layer 15. The intermediate joining layer 15 is constituted by, for example, an adhesive such as a silicone resin, an acrylic resin, or an epoxy resin. The intermediate joining layer 15 may contain a filler such as ceramic powder. Note that the thickness (the dimension in the Z-axis direction) of the intermediate joining layer 15 is, for example, about 0.1 mm to 1.0 mm.

As shown in FIGS. 1 and 2, the base member 20 has an upper surface 21 and a lower surface 22 that is provided on a side opposite to the upper surface 21 in a thickness direction (that is, the Z-axis direction) of the base member 20, and has a columnar shape. Although it is preferable for the base member 20 to be made of a metal (such as aluminum or an aluminum alloy), the base member 20 may be made of a material other than a metal (such as ceramic). Note that the base member 20 of the present embodiment is made of a metal. The diameter of the base member 20 is, for example, about 220 mm to 550 mm (ordinarily, about 220 mm to 350 mm), and the thickness (the dimension in the Z-axis direction) of the base member 20 is, for example, about 20 mm to 40 mm. The upper surface 21 is an example of a “fifth surface” of the present disclosure, and the lower surface 22 is an example of a “sixth surface” of the present disclosure.

Note that a refrigerant flow path 23 for allowing a refrigerant (such as a fluorine-based inert liquid or water) to flow therethrough is formed in the base member 20, and that, by causing the refrigerant to flow in the refrigerant flow path 23, the base member 20 is cooled to thereby cool the plate-shaped member 10 through the joining layer 30.

As shown in FIGS. 1 and 2, the joining layer 30 is disposed between the lower surface 12 of the plate-shaped member 10 and the upper surface 21 of the base member 20, and joins the plate-shaped member 10 and the base member 20 to each other. The joining layer 30 is thicker than the intermediate joining layer 15. As shown in FIG. 3, when viewed in the Z-axis direction (when viewed from the stacking direction), an outer periphery of the joining layer 30 is positioned so as to substantially match the position of the outer periphery of the second plate-shaped member 120. Therefore, the outer periphery of the joining layer 30 is positioned on an outer side with respect to the outer periphery of the intermediate joining layer 15. Since the outer periphery of the second plate-shaped member 120 is larger than the outer periphery of the holding surface 11, the outer periphery of the joining layer 30 is positioned on the outer side with respect to the outer periphery of the holding surface 11.

Note that the joining layer 30 is an example of a “second joining layer” of the present disclosure. The lower surface 12 of the plate-shaped member 10 and the upper surface 21 of the base member 20 are thermally connected to each other by the joining layer 30. The joining layer 30 is constituted by, for example, an adhesive such as a silicone resin, an acrylic resin, or an epoxy resin. Note that the thickness (the dimension in the Z-axis direction) of the joining layer 30 is, for example, about 0.1 mm to 1.0 mm, and is larger than the thickness of the intermediate joining layer 15.

As shown in FIGS. 1 and 2, the electrostatic chuck 1 having such a structure includes a substantially annular O ring 40 that is disposed so as to surround an outer periphery of a layered body including the second plate-shaped member 120, the intermediate joining layer 15, and the joining layer 30. The O ring 40 is made of, for example, an insulating material such as rubber. The O ring 40 is disposed in close contact with a lower surface of the flange portion 114 of the first plate-shaped member 110 and the upper surface 21 of the base member 20. Therefore, when the electrostatic chuck 1 is used, the joining layer 30 and the intermediate joining layer 15 are prevented from being exposed to and corroded by plasma or the like.

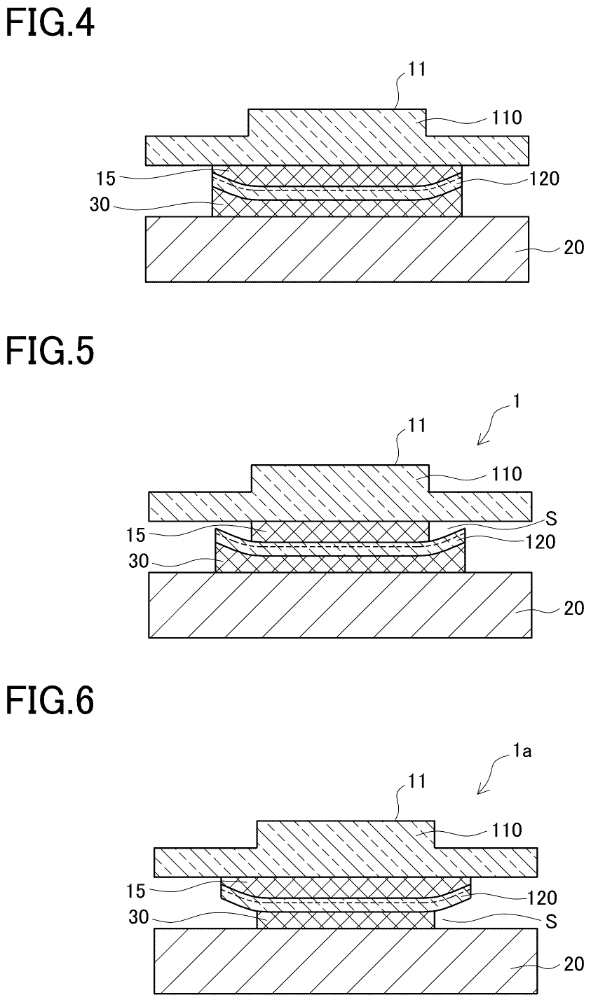

Here, in the electrostatic chuck 1 of the present embodiment, the plate-shaped member 10 includes two plate-shaped members of the plate-shaped member 110 and the plate-shaped member 120 (including the intermediate joining layer 15), and thus each of the plate-shaped members 110 and 120 becomes thin in its thickness. Therefore, as shown in FIG. 4, when joining the second plate-shaped member 120 to the base member 20, although the second plate-shaped member 120 is partly unwarped, the warp may remain on the outer side of the second plate-shaped member 120 to completion of a product. This is because, the joining layer 30 does not exist on an outer side with respect to an outermost periphery of the second plate-shaped member 120, and thus a force that causes the warping to follow the base member 20 does not act from the surrounding, so that unwarping is unlikely to be performed on the outer side of the second plate-shaped member 120.

When the warp remains on the outer side of the second plate-shaped member 120, variations in the thickness of the joining layer 30 are increased at an outer portion thereof. For example, as shown in FIG. 4, when the second plate-shaped member 120 is warped in a convex form on a lower side (convex form on a side of the base member 20) of the second plate-shaped member 120, at an outer side of the joining layer 30 that joins the base member 20 and the second plate-shaped member 120 to each other, the thickness of the joining layer 30 is increased toward an outer periphery, whereas, at an outer side of the intermediate joining layer 15 that joins the first plate-shaped member 110 and the second plate-shaped member 120 to each other, the thickness of the intermediate joining layer 15 is decreased toward the outer periphery.

In this way, when variations in the thickness of the joining layer 15 and variations in the thickness of the joining layer 30 are increased, variations in heat conduction at the joining layers 15 and 30 are increased. In other words, a large difference occurs between the heat conduction at portions where variations of the thicknesses of the joining layers 15 and 30 are small and the heat conduction at portions where variations in the thicknesses of the joining layers 15 and 30 are large, which could adversely affect temperature uniformity at the holding surface 11.

Therefore, in the electrostatic chuck 1 of the present embodiment, when viewed in the Z-axis direction, the intermediate joining layer 15 is disposed such that the outer periphery of the intermediate joining layer 15 is positioned at a location that is retreated on the inner side with respect to the outer periphery of the second plate-shaped member 120. Therefore, as shown in FIG. 5, the intermediate joining layer 15 is eliminated at an outer portion where variations in the thickness of the intermediate joining layer 15 and variations in the thickness of the joining layer 30 are increased due to the warping of the second plate-shaped member 120. In other words, the intermediate joining layer 15 is no longer formed (does not exist) at the outer portion where variations in the thickness of the intermediate joining layer 15 and variations in the thickness of the joining layer 30 are increased.

Therefore, a space S is formed between an outer portion of the second plate-shaped member 120 and the first plate-shaped member 110. Note that the space S becomes a vacuum when the device is used. There is almost no heat conduction in the space S. Therefore, heat moves between the second plate-shaped member 120 and the first plate-shaped member 110 through the intermediate joining layer 15 where variations in the thickness are decreased.

Here, heat moves between the second plate-shaped member 120 and the base member 20 through the joining layer 30 where variations in the thickness are large, and accordingly, the amount of movement of the heat at the outer portion of the second plate-shaped member 120 where the joining layer 30 is thick is decreased. However, the space S is formed without the intermediate joining layer 15 between the outer portion of the second plate-shaped member 120 and the first plate-shaped member 110, and accordingly, almost no movement of heat occurs between the outer portion of the second plate-shaped member 120 and the first plate-shaped member 110.

Therefore, heat moves between the base member 20 and the first plate-shaped member 110 through a portion of the joining layer 30 where variations in the thickness are small, a portion of the second plate-shaped member 120 where warping is suppressed, and the intermediate joining layer 15. Therefore, the movement of heat between the first plate-shaped member 110 and the second plate-shaped member 120 and the movement of heat between the first plate-shaped member 110 and the base member 20 become uniform. As a result, it is possible to improve temperature uniformity at the holding surface 11 that holds the semiconductor wafer W.

In the electrostatic chuck 1 of the present embodiment, when viewed in the Z-axis direction, the outer periphery of the intermediate joining layer 15 and the outer periphery of the joining layer 30 are positioned on the outer side with respect to the outer periphery of the holding surface 11. That is, the outer periphery of the intermediate joining layer 15 and the outer periphery of the joining layer 30 are not positioned on the inner side with respect to the outer periphery of the holding surface 11. In other words, the surface area of the intermediate joining layer 15 and the surface area of the joining layer 30 are larger than the surface area of the holding surface 11. Therefore, heat reliably moves between the first plate-shaped member 110 (the portion where the holding surface 11 exists) and the base member 20 through the intermediate joining layer 15 and the joining layer 30, and thus temperature uniformity at the holding surface 11 can be reliably improved.

In the electrostatic chuck 1 of the present embodiment, when viewed in the Z-axis direction, the outer periphery of the joining layer 30 is positioned on the outer side with respect to the outer periphery of the intermediate joining layer 15. Therefore, the contact area where the second plate-shaped member 120 and the joining layer 30 contact each other becomes larger than the contact area where the second plate-shaped member 120 and the intermediate joining layer 15 contact each other. In addition, since the bending rigidity of the base member 20 is higher than the bending rigidity of the second plate-shaped member 120, it is possible to effectively unwarp the second plate-shaped member 120 by causing the second plate-shaped member 120 to reliably follow the base member 20. In this way, the second plate-shaped member 120 is effectively unwarped, and thus variations in the thickness of the intermediate joining layer 15 and variations in the thickness of the joining layer 30 can be decreased. As a result, the movement of heat between the first plate-shaped member 110 and the second plate-shaped member 120 and the movement of heat between the base member 20 and the second plate-shaped member 120 are made more uniform, further improving temperature uniformity at the holding surface 11.

Further, in the electrostatic chuck 1 of the present embodiment, the joining layer 30 is thicker than the intermediate joining layer 15. Therefore, it is possible to reliably prevent damage to the joining layer 30 caused by a difference between the thermal expansion coefficient of the second plate-shaped member 120 (made of ceramic) and the thermal expansion coefficient of the base member 20 (made of a metal). Consequently, it is possible to properly conduct heat between the second plate-shaped member 120 and the base member 20 through the joining layer 30. As a result, temperature uniformity at the holding surface 11 can be reliably improved.

As described above, according to the electrostatic chuck 1 of the present embodiment, when viewed in the Z-axis direction, the outer periphery of the intermediate joining layer 15 is positioned at a location that is retreated on the inner side with respect to the outer periphery of the second plate-shaped member 120. Therefore, the intermediate joining layer 15 is eliminated and the space S is formed at the outer portion where variations in the thickness of the intermediate joining layer 15 and variations in the thickness of the joining layer 30 are increased due to warping of the second plate-shaped member 120. Since there is almost no heat conduction in this space S, heat moves between the second plate-shaped member 120 and the first plate-shaped member 110 through the intermediate joining layer 15 where variations in the thickness are decreased. Therefore, the movement of heat between the first plate-shaped member 110 and the second plate-shaped member 120 and the movement of heat between the first plate-shaped member 110 and the base member 20 become uniform, thereby achieving improvement in temperature uniformity at the holding surface 11 that holds semiconductor wafer W.

### Second Embodiment

Next, a second embodiment is described with reference to FIG. 6. Although the second embodiment has the same basic structure as the first embodiment, the second embodiment differs from the first embodiment in that the bending rigidity of a first plate-shaped member 110 is higher than the bending rigidity of a second plate-shaped member 120. Note that, although the first plate-shaped member 110 and the second plate-shaped member 120 are each made of ceramic, the first plate-shaped member 110 is more resistant to warping (flexing) than the second plate-shaped member 120. Therefore, structural portions that correspond to those of the first embodiment are given the same reference numerals and are omitted their explanation as appropriate, and the difference of the second embodiment from the first embodiment is mainly described.

In an electrostatic chuck 1a of the present embodiment, since the first plate-shaped member 110 is more resistant to warping (flexing) than the second plate-shaped member 120, the second plate-shaped member 120 is caused to follow the first plate-shaped member 110 instead of a base member 20 to suppress warping of the second plate-shaped member 120. Therefore, in the electrostatic chuck 1a, as shown in FIG. 6, when viewed in the Z-axis direction, an outer periphery of an intermediate joining layer 15 is positioned on an outer side with respect to an outer periphery of a joining layer 30.

Thus, the contact area where the second plate-shaped member 120 and the intermediate joining layer 15 contact each other is larger than the contact area where the second plate-shaped member 120 and the joining layer 30 contact each other. Therefore, it is possible to effectively unwarp the second plate-shaped member 120 by causing the second plate-shaped member 120 to follow the first plate-shaped member 110 whose bending rigidity is higher than the bending rigidity of the second plate-shaped member.

In this way, in the second embodiment, the second plate-shaped member 120 is unwarped and becomes smaller, and thus variations in the thickness of the intermediate joining layer 15 and variations in the thickness of the joining layer 30 can be decreased. Therefore, the movement of heat between the base member 20 and the second plate-shaped member 120 and the movement of heat between the second plate-shaped member 120 and the first plate-shaped member 110 become more uniform. As a result, temperature uniformity at a holding surface 11 is further improved.

Note that the embodiments above are merely exemplifications and do not limit the present disclosure in any way, and naturally various improvements and modifications are possible with a scope that does not depart from the spirit of the present disclosure. For example, in the embodiments above, the case in which the present disclosure is applied to an electrostatic chuck has been exemplified, but the present disclosure is not limited to an electrostatic chuck and can be applied to holding devices in general that hold an object on its surface.

In the embodiments mentioned above, the case in which the second plate-shaped member 120 is warped (or flexed) has been exemplified, but the present disclosure can be applied to a case in which the first plate-shaped member 110 is warped (or flexed). Further, in the embodiments mentioned above, the case in which the second plate-shaped member 120 is warped in a convex form on the lower side (convex form on the side of the base member 20) of the second plate-shaped member 120 has been exemplified, but the present disclosure can also be applied to a case in which the second plate-shaped member 120 (or the first plate-shaped member 110) is warped in a convex form on an upper side (convex form on a side of the holding surface 11) of the second plate-shaped member 120 (or the first plate-shaped member 110).

In the embodiments mentioned above, the case in which the intermediate joining layer 15 or the joining layer 30 is disposed so as to be retreated (disposed on the inner side) with respect to the outer periphery of the second plate-shaped member 120 has been exemplified, but both the intermediate joining layer 15 and the joining layer 30 can be disposed so as to be retreated with respect to the outer periphery of the second plate-shaped member 120. In this case, when viewed in the Z-axis direction, the outer periphery of the intermediate joining layer 15 and the outer periphery of the joining layer 30 need to be disposed so as not to match each other. Namely, the outer periphery of the intermediate joining layer 15 and the outer periphery of the joining layer 30 need to be disposed so as to be displaced from each other.

In the embodiments above, the case in which the first plate-shaped member 110 includes a flange portion 114 has been exemplified, but the first plate-shaped member 110 needs not include a flange portion 114.

### REFERENCE SIGNS LIST

1 Electrostatic chuck
11 Holding surface
15 Intermediate joining layer
20 Base member
30 Joining layer
110 First plate-shaped member
120 Second plate-shaped member
W Semiconductor wafer

What is claimed is:

1. A holding device comprising:
a first plate-shaped member of a disk shape that has a first surface and a second surface provided on a side opposite to the first surface;
a second plate-shaped member of a disk shape that has a third surface and a fourth surface provided on a side opposite to the third surface, that includes a heating resistor, and that has a diameter larger than a diameter of the first surface;
a first joining layer that is disposed between the second surface and the third surface and that joins the first plate-shaped member and the second plate-shaped member to each other;
a base member that has a fifth surface and a sixth surface provided on a side opposite to the fifth surface; and
a second joining layer that is disposed between the fourth surface and the fifth surface and that joins the second plate-shaped member and the base member to each other,
wherein, in the holding device that holds an object on the first surface of the first plate-shaped member,
when viewed from a stacking direction of the first plate-shaped member, the second plate-shaped member, and the base member, an outer periphery of at least one of the first joining layer and the second joining layer is positioned at a location that is retreated on an inner side with respect to an outer periphery of the second plate-shaped member.

2. The holding device according to claim 1,
wherein, when viewed from the stacking direction, the outer periphery of the first joining layer and the outer periphery of the second joining layer are positioned on an outer side with respect to an outer periphery of the first surface.

3. The holding device according to claim 1,
wherein, when a bending rigidity of the base member is higher than a bending rigidity of the second plate-shaped member, the outer periphery of the second joining layer is positioned on an outer side with respect to the outer periphery of the first joining layer, when viewed from the stacking direction.

4. The holding device according to claim 1,
wherein, when a bending rigidity of the first plate-shaped member is higher than a bending rigidity of the second plate-shaped member, the outer periphery of the first joining layer is positioned on an outer side with respect to the outer periphery of the second joining layer, when viewed from the stacking direction.

5. The holding device according to claim 1,
wherein, when the second plate-shaped member and the base member are made of different types of materials and there is a difference between a thermal expansion coefficient of the second plate-shaped member and a thermal expansion coefficient of the base member, the second joining layer is made thicker than the first joining layer.

6. The holding device according to claim 2,
wherein, when a bending rigidity of the base member is higher than a bending rigidity of the second plate-shaped member, the outer periphery of the second joining layer is positioned on an outer side with respect to the outer periphery of the first joining layer, when viewed from the stacking direction.

7. The holding device according to claim 2,
wherein, when a bending rigidity of the first plate-shaped member is higher than a bending rigidity of the second plate-shaped member, the outer periphery of the first joining layer is positioned on an outer side with respect to the outer periphery of the second joining layer, when viewed from the stacking direction.

8. The holding device according to claim 2,
wherein, when the second plate-shaped member and the base member are made of different types of materials and there is a difference between a thermal expansion coefficient of the second plate-shaped member and a thermal expansion coefficient of the base member, the second joining layer is made thicker than the first joining layer.

9. The holding device according to claim 3,
wherein, when the second plate-shaped member and the base member are made of different types of materials and there is a difference between a thermal expansion coefficient of the second plate-shaped member and a thermal expansion coefficient of the base member, the second joining layer is made thicker than the first joining layer.

10. The holding device according to claim 4,
wherein, when the second plate-shaped member and the base member are made of different types of materials and there is a difference between a thermal expansion coefficient of the second plate-shaped member and a thermal expansion coefficient of the base member, the second joining layer is made thicker than the first joining layer.

11. The holding device according to claim 6,
wherein, when the second plate-shaped member and the base member are made of different types of materials and there is a difference between a thermal expansion coefficient of the second plate-shaped member and a thermal expansion coefficient of the base member, the second joining layer is made thicker than the first joining layer.

12. The holding device according to claim 7,
wherein, when the second plate-shaped member and the base member are made of different types of materials and there is a difference between a thermal expansion coefficient of the second plate-shaped member and a thermal expansion coefficient of the base member, the second joining layer is made thicker than the first joining layer.
